(19) United States
(12) Patent Application Publication
(10) Pub. No.: US 2026/0212938 A1
(43) Pub. Date: Jul. 23, 2026

(54) MEMORY DEVICE AND METHOD OF OPERATING THE SAME

(71) Applicant: Taiwan Semiconductor Manufacturing Company, Ltd., Hsinchu (TW)

(72) Inventors: Ji-Kuan Lee, Taichung City (TW); Chia-En Huang, Hsinchu County (TW); Yao-Jen Yang, Hsinchu County (TW); Ting-Wei Chiang, New Taipei City (TW)

(73) Assignee: Taiwan Semiconductor Manufacturing Company, Ltd., Hsinchu (TW)

(21) Appl. No.: 19/034,526

(22) Filed: Jan. 22, 2025

(51) Int. Cl. G11C 17/16; G11C 5/06; H10B 20/25

(52) U.S. Cl. CPC G11C 17/165; G11C 5/063; H10B 20/25

(57) ABSTRACT

Provided is a memory device including: a first memory cell disposed over an active region. The first memory cell may include: a first transistor comprising: a first gate structure extending across the active region, a first source/drain structure and a second source/drain structure disposed on the active region at opposite sides of the first gate structure; and a first anti-fuse structure connected in series with the first transistor, and comprising: a first electrode over the first source/drain structure, the first source/drain structure used as a second electrode and a first insulator vertically sandwiched between the first electrode and the second electrode.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device, in accordance with some embodiments.

FIG. 2 illustrates an example circuit diagram of a portion of the memory device of FIG. 1, in accordance with some embodiments.

FIG. 3 illustrates an example layout to fabricate a pair of the memory cells of FIG. 2, in accordance with some embodiments.

FIG. 4 illustrates a cross-sectional view of one of the memory cells, made based on the layout of FIG. 3 taken along the line A-A, in accordance with some embodiments.

FIG. 5 illustrates a cross-sectional view of one of the memory cells, made based on the layout of FIG. 3 taken along the line B-B, in accordance with some embodiments.

FIG. 6 illustrates a cross-sectional view of one of the memory cells, made based on the layout of FIG. 3 taken along the line C-C, in accordance with some embodiments.

FIG. 7 illustrates an example flow chart of a method for operating at least one of the memory cells of FIG. 2, in accordance with some embodiments.

FIG. 8 illustrates an example circuit diagram of a portion of the memory device, in accordance with some alternative embodiments.

FIG. 9 illustrates an example layout to fabricate a pair of the memory cells of FIG. 8, in accordance with some alternative embodiments.

FIG. 10 to FIG. 12 illustrate cross-sectional views of one of the memory cells, made based on the layout of FIG. 9 taken along the line A-A, the line B-B, and line C-C respectively, in accordance with some alternative embodiments.

FIG. 13 illustrates an example circuit diagram of a portion of the memory device, in accordance with some alternative embodiments.

FIG. 14 illustrates an example layout to fabricate a pair of the memory cells of FIG. 13, in accordance with some alternative embodiments.

FIG. 15 to FIG. 17 illustrate cross-sectional views of one of the memory cells, made based on the layout of FIG. 14 taken along the line A-A, the line B-B, and line C-C respectively, in accordance with some alternative embodiments.

FIG. 18 illustrates an example layout to fabricate the memory device, in accordance with some embodiments.

FIG. 19 illustrates an example layout to fabricate the memory device, in accordance with some alternative embodiments.

FIG. 20 illustrates an example layout to fabricate a pair of the memory cells of FIG. 2, in accordance with some alternative embodiments.

FIG. 21 to FIG. 23 illustrate cross-sectional views of one of the memory cells, made based on the layout of FIG. 20 taken along the line A-A, the line B-B, and line C-C respectively, in accordance with some alternative embodiments.

FIG. 24 illustrates an example layout to fabricate a pair of the memory cells of FIG. 2, in accordance with some other embodiments.

FIG. 25 illustrates a cross-sectional view of one of the memory cells, made based on the layout of FIG. 24 taken along the line B-B, in accordance with some other embodiments.

FIG. 26A to FIG. 26F are top views showing a via structure in accordance with various embodiments.

FIG. 27 illustrates a cross-sectional view of one of the memory cells, made based on the layout of FIG. 3 taken along the line B-B, in accordance with some alternative embodiments.

FIG. 28 illustrates a cross-sectional view of one of the memory cells, made based on the layout of FIG. 3 taken along the line B-B, in accordance with some other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated circuits (ICs) sometimes include one-time-programmable (OTP) memories to provide non-volatile memory (NVM) in which data are not lost when the IC is powered off. One type of the OTP devices includes anti-fuse memory devices. The anti-fuse memory device include a number of anti-fuse memory cells (or bit cells), whose terminals are disconnected before programming, and are shorted (e.g., connected) after the programming. The anti-fuse memory device may be based on metal-oxide-semiconductor (MOS) technology. For example, an anti-fuse memory cell may include a programming MOS transistor and at least one reading MOS transistor coupled in series. A gate dielectric of the programming MOS transistor may be broken down to cause the gate and the source or drain of the programming MOS transistor to be interconnected. Depending on whether the gate dielectric of the programming MOS transistor is broken down, different data bits can be presented by the anti-fuse memory cell through reading a resultant current flowing through the programming MOS transistor and reading MOS transistor. The anti-fuse memory devices have the advantageous features of reverse-engineering proofing, since the programming states of the anti-fuse cells cannot be determined through reverse engineering.

As integrated circuit devices get scaled down, the anti-fuse memory devices use a high voltage and become more unbearable in advanced nodes. Therefore, while the anti-fuse memory device designs are generally adequate for their intended purposes, they are not satisfactory in all aspects.

The present disclosure provides various embodiments of an anti-fuse memory device including a number of anti-fuse memory cells. Each of the anti-fuse memory cells, as disclosed herein, includes an anti-fuse structure and a reading transistor. The anti-fuse structure and the reading transistor are electrically coupled to each other in series. In various embodiments, the anti-fuse structure may be implemented as a first electrode and a second electrode sandwiching an insulator. One of the first or second electrode is configured to break down at least a portion of the insulator so as to electrically couple (e.g., short) the first electrode to the second electrode. Stated another way, the anti-fuse structure may not include a transistor as being typically implemented in the existing anti-fuse memory devices. With such a non-transistor anti-fuse structure, the bit cell area can be effectively reduced to accommodate the advanced technology. In various embodiments of the present disclosure, the first second electrode can be implemented as a via structure that can be compatibly fabricated with the existing CMOS technologies. Accordingly, no additional fabrication cost or complexity should be incurred. Further, by forming one of the electrodes over one of the source/drain structure, two of the disclosed anti-fuse memory cells can be compactly formed in such a single active region. Accordingly, a total area of such a pair of anti-fuse memory cells can be significantly reduced.

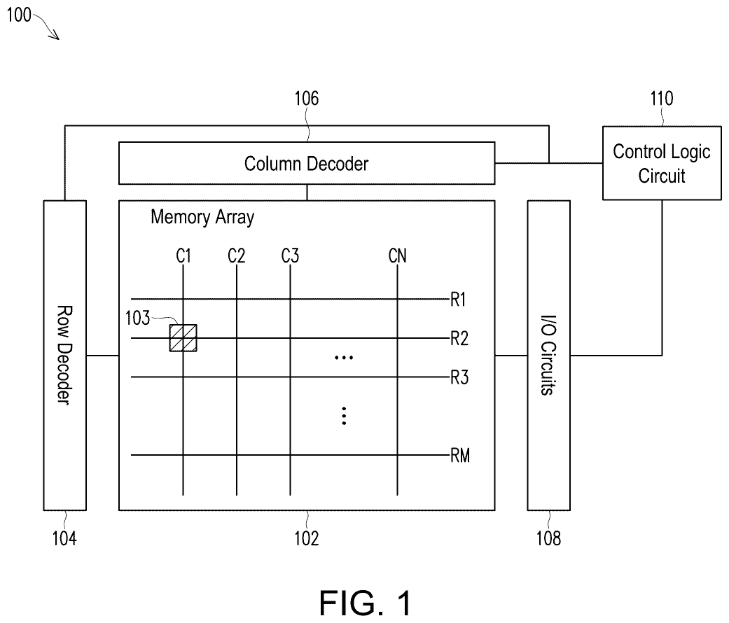

FIG. 1 illustrates a memory device 100, in accordance with various embodiments. As shown, the memory device 100 includes a memory array 102, a row decoder 104, a column decoder 106, an input/output (I/O) circuit 108, and a control logic circuit 110. Despite not being shown in FIG. 1, all of the components of the memory device 100 may be operatively coupled to each other and to the control logic circuit 112. Although, in the illustrated embodiment of FIG. 1, each component is shown as a separate block for the purpose of clear illustration, in some other embodiments, some or all of the components shown in FIG. 1 may be integrated together. For example, the memory array 102 may include an embedded I/O circuit 108.

The memory array 102 is a hardware component that stores data. In one aspect, the memory array 102 is implemented as a semiconductor memory device. The memory array 102 includes a number of memory cells (or otherwise storage units) 103. The memory array 102 includes a number of rows R1, R2, R3 . . . RM, each extending in a first direction (e.g., X-direction) and a number of columns C1, C2, C3 . . . CN, each extending in a second direction (e.g., Y-direction). Each of the rows/columns may include one or more conductive structures each configured as an access line (e.g., a programming word line (WLP), a reading word line (WLR), a bit line (BL)), which will be discussed below. In some embodiments, each memory cell 103 is arranged in the intersection of a corresponding row and a corresponding column and can be operated according to voltages or currents through the respective conductive structures of the column and row.

In various embodiments of the present disclosure, each memory cell 103 is implemented as an anti-fuse memory cell that includes an anti-fuse structure and a transistor coupled in series. The anti-fuse structure can function as a programming part of the memory cell, and the transistor can function as a reading transistor of the memory cell. The anti-fuse structure can be programmed by a WLP, and the transistor can be gated by a WLR. The anti-fuse structure can at least be formed by a number of interconnect structures of a middle-end-of-line (MEOL) networking, for example, a first via structure connecting to a gate structure and a second via structure coupling to a source/drain structure that interpose an insulator therebetween, which will be discussed below. Although the present disclosure is directed to implementing the memory cell 103 as an anti-fuse memory cell, it should be understood that the memory cell 103 can include any of various other memory cells, while remaining within the scope of present disclosure.

The row decoder 104 is a hardware component that can receive a row address of the memory array 102 and assert a conductive structure (e.g., a word line) at that row address. The column decoder 106 is a hardware component that can receive a column address of the memory array 102 and assert one or more conductive structures (e.g., a bit line, a source line) at that column address. The I/O circuit 108 is a hardware component that can access (e.g., read, program) each of the memory cells 103 asserted through the row decoder 104 and column decoder 106. The control logic circuit 110 is a hardware component that can control the coupled components (e.g., 102 through 108).

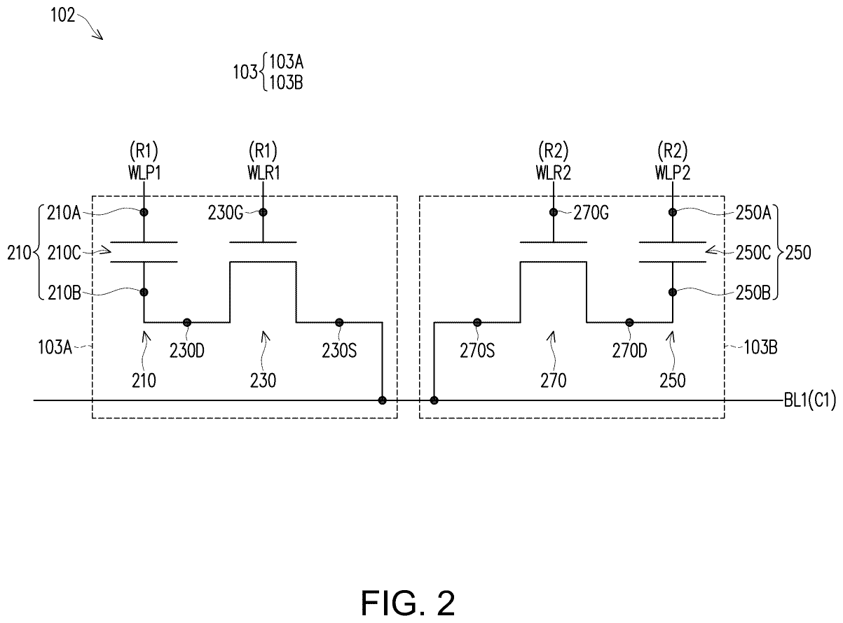

FIG. 2 illustrates an example circuit diagram of a portion of the memory device 100 (e.g., some of the memory cells 103), in accordance with some embodiments. In the illustrated example of FIG. 2, anti-fuse memory cells 130A and 130B of the memory array 102 are shown. Although two anti-fuse memory cells 130A and 130B are shown, it should be appreciated that the memory array 102 can have any number of anti-fuse memory cells, while remaining within the scope of present disclosure.

As mentioned above, the memory cells 103 can be arranged as an array. In FIG. 2, the memory cells 103A and 103B may be disposed in a same row but in respectively different columns. For example, the memory cells 103A and 103B are disposed in column C1, but in rows R1 and R2, respectively. However, the embodiments of the present invention are not limited thereto. In other embodiments, the memory cells 103 may arranged into an array with multiple rows (e.g., R1, R2, R3 . . . RM) and columns (e.g., C1, C2, C3 . . . CN). With such a configuration, each of the memory cells can be operatively coupled to the access lines in the corresponding row and column, respectively.

For example in FIG. 2, the memory cell 103A is operatively (e.g., electrically) coupled to a programming word line and a reading word line in row R1 (hereinafter WLP1 and WLR1, respectively) and to a bit line in column C1 (hereinafter BL1); and the memory cell 103B is operatively coupled to a programming word line and a reading word line in row R2 (hereinafter WLP2 and WLR2, respectively) and to the BL1 in column C1.

In some embodiments, each of the memory cells 130A and 130B can be operatively coupled to the I/O circuit 108 through the respective WLR, WLP, and BL for being accessed (e.g., programmed, read). For example, the I/O circuit 108 can cause the row decoder 104 to assert the WLP1 and WLR1 and the column decoder 106 to assert the BL1, so as to access the memory cell 103A through the WLP1, WLR1, and BL1. Accordingly, each of the memory cells 130A and 130B can be individually selected to be programmed or read. Details of programming and reading the memory cell will be discussed in further detail below.

As disclosed herein, each of the memory cells 103A to 103B includes an anti-fuse structure configured for programming and a transistor configured for reading, wherein the anti-fuse structure and the transistor are coupled to each other in series. The anti-fuse structure may be embodied as a non-transistor structure, for example, a structure having a first electrode and a second electrode interposing an insulator therebetween. Specifically, one of the electrodes of the anti-fuse structure (implemented as a first via structure) is coupled to a WLP, and the other of the electrodes of the anti-fuse structure (implemented as one of the epitaxial structures) is electrically coupled to one of the source/drain structures of the transistors; and the transistor is gated by a WLR, with the other of the source/drain structures electrically coupled to a BL, in accordance with various embodiments. The memory cell 103A is selected as a representative example in the following discussions.

Referring still to FIG. 2, the memory cell 103A includes a (programming) anti-fuse structure 210, and a (reading) transistor 230. The programming anti-fuse structure 210 is coupled to the reading transistor 230 in series. The anti-fuse structure 210 has a first electrode 210A and a second electrode 210B that interpose an insulator 210C; and the transistor 230 has a first terminal (implemented as a drain structure) 230D, a second terminal (implemented as a gate structure) 230G, and a third terminal (implemented as a source structure) 230S. In various embodiments, the anti-fuse structure 210 has the first electrode 210A, which is formed as a first via structure (sometimes referred to as “VD”), connected to WLP1. Further, the anti-fuse structure 210 has the second electrode 210B, which is formed as a first epitaxial structure (e.g., the drain structure 230D), thereby serially connecting the anti-fuse structure 210 to the transistor 230. The transistor 230 is gated by WLR1, with the source structure 230S electrically coupled to BL1.

Similarly, the memory cell 103B includes a (programming) anti-fuse structure 250, and a (reading) transistor 270. The programming anti-fuse structure 250 is coupled to the reading transistor 270 in series. The anti-fuse structure 250 has a first electrode 250A and a second electrode 250B that interpose an insulator 250C; and the transistor 270 has a first terminal (implemented as a drain structure) 270D, a second terminal (implemented as a gate structure) 270G, and a third terminal (implemented as a source structure) 270S. In various embodiments, the anti-fuse structure 250 has the first electrode 250A, which is formed as a second via structure (sometimes referred to as “VD”), connected to WLP2. Further, the anti-fuse structure 250 has the second electrode 250B, which is formed as a second epitaxial structure (e.g., the drain structure 270D), thereby serially connecting the anti-fuse structure 250 to the transistor 270. The transistor 270 is gated by WLR2, with the source structure 270S electrically coupled to BL1.

In accordance with various embodiments of the present disclosure, some of the features/structures of the anti-fuse structure 210 (e.g., 210B) is a portion of one of the source/drain structures (e.g., 230D) of the transistors 230, which is fabricated by a front-end-of-line (FEOL) process. The other features/structures of the anti-fuse structure 210 (e.g., VD) is a portion of a middle-end-of-line (MEOL) networking, which generally refers to a collection of interconnect structures of a “middle networking” between a front-end-of-line (FEOL) networking and a back-end-of-line (BEOL) networking. The terms FEOL networking and BEOL networking typically refer to a collection of active/dummy features formed along the major surface of a substrate (e.g., a transistor and its features/structures) and a collection of interconnect structures (e.g., MO) formed in one or more metallization layers over the substrate, respectively. Details of these FEOL/MEOL/BEOL structures that construct at least a portion of the memory array 102 will be discussed below.

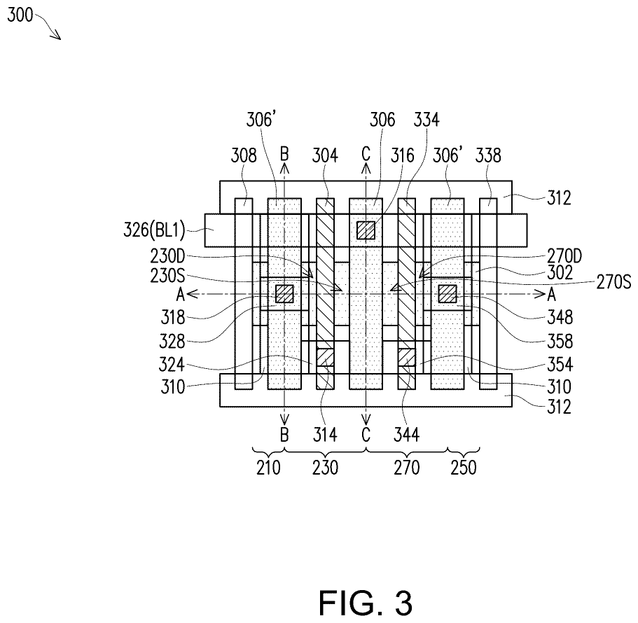

FIG. 3 illustrates an example layout 300 of a portion of the memory array 102, which includes two of the disclosed anti-fuse memory cells coupled to a same bit line (e.g., 103A and 103B of FIG. 2), in accordance with various embodiments. As will be discussed below, these two memory cells may share (e.g., be formed over) a common active region, which can advantageously reduce an area of the memory array 102 as a whole.

As shown, the layout 300 includes: pattern 302 that is configured to form an active region (hereinafter “active region 302”); patterns 304, 308, 334, and 338 that are each configured to form a gate structure (hereinafter “gate structure 304,” “gate structure 308,” “gate structure 334,” and “gate structure 338,” respectively); a number of patterns 312 that are each configured to form a dielectric structure separating or otherwise cutting a corresponding gate structure (hereinafter “cut structure 312”); patterns 306 and 306′ that are each configured to form a source/drain interconnect structure, e.g., MD, (hereinafter “MD 306” and “MD 306,” respectively); a number of patterns 310 that are each configured to form a dielectric structure separating or otherwise cutting a corresponding MD (hereinafter “cut structure 310”); patterns 314 and 344 that are each configured to form a gate via structure, e.g., VG (hereinafter “VG 314” and “VG 344,” respectively); patterns 316, 318, and 348 that are each configured to form a source/drain via structure, e.g., VD (hereinafter “VD 316,” “VD 318,” and “VD 348,” respectively); patterns 324, 354, 328, 358 that are each configured to form an interconnect structure in a bottommost metallization layer, e.g., M0 (hereinafter “M0 324,” “M0 354,” “M0 328,” and “M0 358,” respectively); and a pattern 326 that is configured to form a bit line in a metallization layer, e.g., BL1.

The active region 302 may extend along a first lateral direction (e.g., X-direction), while the gate structures 304, 334, 308, 338 and MD 306 may extend along a second, different lateral direction (e.g., Y-direction). Further, the gate structures 308 and 338 may extend along opposite edges of the active region 302, while the gate structures 304 and 334 may each travel across a non-edge portion of the active region 302. Interposed between adjacent ones of the gate structures, one of the MDs can travel across the active region 302. For example in FIG. 3, the MD 306 travels across a portion of the active region 302 between the gate structures 304 and 334. In some embodiments, each of the cut structures 312 can (e.g., along the X-direction) travel across a corresponding gate structure to cut it into a number of separated portions. For example in FIG. 3, two cut structures 312 travel across each of the gate structures 304 and 334 to cut it into one continuous portion. In some embodiments, the cut structures 312 can be formed to isolate a number of memory cells (e.g., 2 memory cells in FIG. 3) from other memory cells of the memory array 102. Further, each of the cut structures 310 may be overlapped with a corresponding MD, so that the region has no MD structure. For example in FIG. 3, one cut structure 310 is overlapped with the MD 306′ between the gate structures 304 and 308, and the other cut structure 310 is overlapped with the MD 306′ between the gate structures 334 and 338. In this case, top surfaces of the drain structures 230D and 270D are free of the MD structure.

The active region 302 can be formed as a (e.g., planar) region recessed in a major surface of a substrate or a (e.g., non-planar) stack structure protruding from the major surface of the substrate. The planar region and the non-planar stack can be used to form a number of planar transistors and a number of non-planar transistors, respectively. The following discussions will be focused on non-planar transistors (e.g., Fin Field-Effect-Transistors (FinFETs), Gate-All-Around (GAA) FETs, complementary field-effect transistors (CFETs), or the like).

For example, to form the (reading) transistors of the disclosed anti-fuse memory cells as GAA FETs, the stack can include a number of semiconductor nanostructures (e.g., nanosheets) extending along the X-direction and vertically separated from each other. Portions of the semiconductor structures in the stack that are overlaid by the gate structures 304 and 334 remain, while other portions are replaced with a number of epitaxial structures.

The remaining portions of the semiconductor structures (i.e., the portions of the active region 302 that are overlaid by the gate structures) can be configured as the channel of a corresponding transistor. The epitaxial structures coupled to both sides (or ends) of the remaining portions of the semiconductor structures can be configured as source/drain structures (or terminals) of the transistor. A portion of the gate structure that overlays (e.g., straddles) the remaining portions of the semiconductor structures can be configured as a gate structures (or terminal) of the transistor.

According to some embodiments of the present disclosure, the gate structures 304 and 334, that are not disposed in edge portions of the active region 302, can serve as respective active gate structures of corresponding transistors; and the gate structures 308 and 338, that are disposed along edges of the active region 302, can serve as dummy gate structures or isolation dummy gates (IDGs). An active gate structure generally refers to the gate that is configured to turn on and off a corresponding transistor, and a dummy gate structure generally refers to the gate that is not configured to turn on or off a corresponding transistor. In some embodiments, one of the IDGs is a dielectric feature that includes one or more dielectric materials (e.g., oxide, nitride, oxynitride, or other suitable materials), and functions as an isolation feature. In some embodiments, one of the IDGs is a type of continuous polysilicon on oxide diffusion (OD) edge structure, and is referred to as a type of CPODE structure.

For example, a first portion of the active region 302 that is overlaid by the gate structure 304 may include a number of nanostructures vertically separated from each other, which can function as a channel of the reading transistor 230 (FIG. 2). The gate structure 304 may function as the gate structure 230G of the reading transistor 230. Portions of the active region 302 that are disposed on opposite sides of the gate structure portion 304 are replaced with epitaxial structures, which can function as the source/drain structures 230D and 230S of the reading transistor 230 (FIG. 2), respectively. Similarly, a second portion of the active region 302 that is overlaid by the gate structure 334 may include a number of nanostructures vertically separated from each other, which can function as a channel of the reading transistor 270 (FIG. 2). The gate structure 334 may function as the gate structure 270G of the reading transistor 270. Portions of the active region 302 that are disposed on opposite sides of the gate structure 334 are replaced with epitaxial structures, which can function as the source/drain structures 270D and 270S of the reading transistor 270, respectively. It should be noted that the reading transistors 230 and 270 may share a same portion of the active region 302 to form their respective source structures 230S and 270S, as shown in FIG. 3.

The MD 306 is formed to connect to a corresponding one of the source/drain structures. For example, the MD 306 connects to the source structure 230S of the reading transistor 230 and the source structure 270S of the reading transistor 270. Further, each of the VGs 314 and 344 is formed to connect to a corresponding one of the gate structures 304 and 334; and the VD 316 is formed to connect to the MD 306. For example, the VG 314 connects to the gate structure 304; the VG 344 connects to the gate structure 334; and the VD 316 connects to the MD 306.

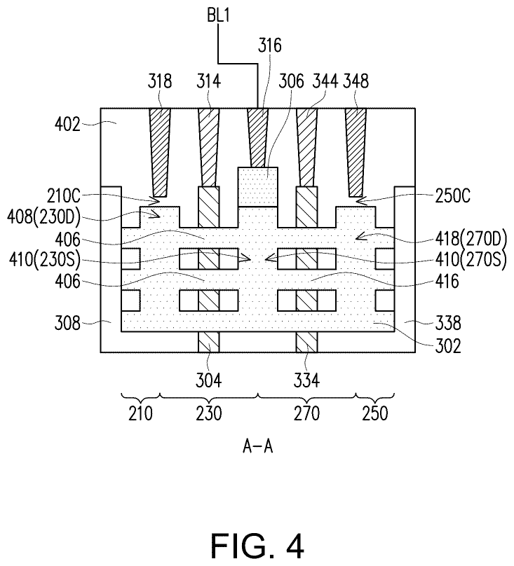

According to various embodiments of the present disclosure, the VD 318 can function as the first electrode 210A and the drain structure 230D directly below the VD 318 can function as the second electrode 210B of the anti-fuse structure 210 (FIG. 2); and the VD 348 can function as the first electrode 250A and the drain structure 270D directly below the VD 348 can function as the second electrode 250B of the anti-fuse structure 250 (FIG. 2). In addition, the VG 314 can function as the gate structure 230G of the reading transistor 230 (FIG. 2); and the VG 344 can function as the gate structure 270G of the reading transistor 270 (FIG. 2). The VGs and VDs are typically formed in a same metallization layer, as will be illustrated in the cross-sectional view of FIG. 4. In general, such a metallization layer includes a dielectric material (sometimes referred to as an interlayer/intermetal dielectric) the embeds a number of interconnect structures. The dielectric material is formed of a low-k dielectric material such as silicon oxide, silicon nitride, silicon carbide, silicon carbonitride, silicon oxynitride, silicon oxycarbonitride, or the like. A portion of such a dielectric material interposed between the electrodes of an anti-fuse structure can function as an insulator of the anti-fuse structure. For example, a first portion of a dielectric material that is interposed between the VD 318 and the drain structure 230D can function as the insulator of the anti-fuse structure 210; and a second portion of the same dielectric material that is interposed between the VD 348 and the drain structure 270D can function as the insulator of the anti-fuse structure 250.

Each of the VGs 314, 344 and VDs 316, 318, 348 is formed to (e.g., electrically) couple an underlying structure to one or more interconnect structures disposed in an upper metallization layer, thereby operatively coupling different anti-fuse memory cells to each other as an array. For example, the VG 314 can couple the gate structure 304 to the M0 324; the VG 344 can couple the gate structure 334 to the M0 354; the VD 318 can be electrically connected to the overlying M0 328; the VD 348 can be electrically connected to the overlying M0 358; and the VD 316 can couple the MD 306 (and the underlying source structures 230S and 270S) to an interconnect structure disposed in an upper metallization layer (e.g., 326) that functions as BL1, which can be better illustrated in the cross-sectional view of FIG. 4.

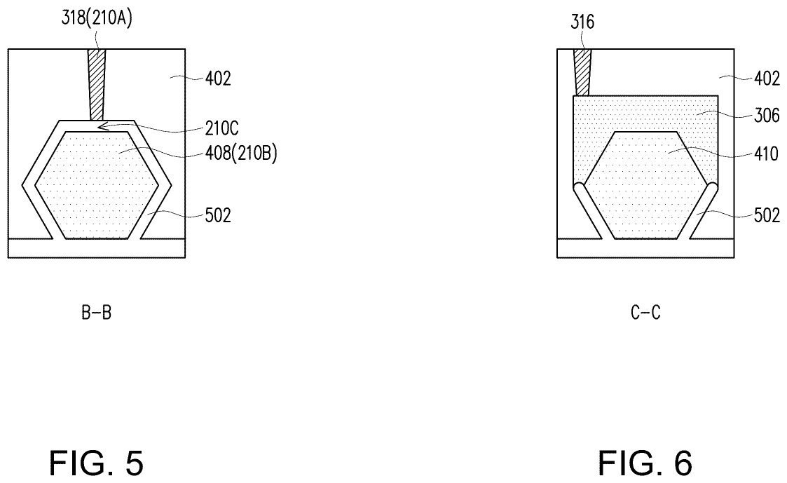

FIG. 4 to FIG. 6 illustrate hybrid cross-sectional views of a portion of the memory array 102 (e.g., the memory cell 103A having the anti-fuse structure 210 and the transistor 230) formed based on the example layout 300 of FIG. 3. Specifically, FIG. 4 includes a cross-section of the portion of the memory array 102, which are cut along line A-A (as indicated in FIG. 3); FIG. 5 includes a cross-section of the portion of the memory array 102, which are cut along line B-B (as indicated in FIG. 3), and FIG. 6 includes a cross-section of the portion of the memory array 102, which are cut along line C-C (as indicated in FIG. 3).

As shown in FIG. 4, the gate structures 304 and 334, the VDs 316, 318, and 348, the VGs 314 and 344, and MD 306 are embedded in a dielectric material 402. The dielectric material 402 includes the above-described low-k dielectric material. As at least partially described above, the VD 318 can function as the first electrode 210A of the anti-fuse structure 210 of the memory cell 103A (FIG. 2), and the epitaxial structure 408 (e.g., the drain structure 230D) can function as the second electrode 210B of the anti-fuse structure 210. A portion of the dielectric material 402 sandwiched between the VD 318 and the epitaxial structure 408 can function as the insulator 210C of the anti-fuse structure 210. The VD 318 may be electrically connected to the M0 328 (FIG. 3) and can function as WLP1 configured to program the anti-fuse structure 210. The epitaxial structure 408 may be electrically connected to the drain structure 230D of the transistor 230 of the memory cell 103A, thereby causing the anti-fuse structure 210 and transistor 230 to be connected to each other in series. In some embodiments, the epitaxial structure 408 may be referred to as a portion of the drain structure 230D of the transistor 230 of the memory cell 103A. The VG 314 may be electrically connected to the gate structure 304 of the transistor 230, and the transistor 230 may be gated by the gate structure 304, which can function as WLR1 that allows access of the memory cell 103A. In addition, the transistor 230 has the source structure 230S connected to the MD 306. The VD 316 can couple the MD 306 (and the source structure 230S) to BL1, which may be formed in an upper metallization layer. Further, a first portion of the active region 302 that is overlaid by the gate structure 304 may include a number of nanostructures vertically separated from each other, which can function as channels 406 of the reading transistor 230. The gate structure 304 may function as the gate structure 230G of the reading transistor 230 (FIG. 2). Portions of the active region 302 that are disposed on opposite sides of the gate structure portion 304 are replaced with epitaxial structures 408 and 410, which can function as the source/drain structures 230D and 230S of the reading transistor 230, respectively. In some embodiments, the epitaxial structure 410 may be referred to as a portion of the source structure 230S of the transistor 230 of the memory cell 103A.

Similarly, the VD 348 can function as the first electrode 250A of the anti-fuse structure 250 of the memory cell 103B (FIG. 2), and the epitaxial structure 418 (e.g., the drain structure 270D) can function as the second electrode 250B of the anti-fuse structure 250. A portion of the dielectric material 402 sandwiched between the VD 348 and the epitaxial structure 418 can function as the insulator 250C of the anti-fuse structure 250. The VD 348 may be electrically connected to the M0 358 (FIG. 3) and can function as WLP2 configured to program the anti-fuse structure 250. The epitaxial structure 418 may be electrically connected to the drain structure 270D of the transistor 270 of the memory cell 103B, thereby causing the anti-fuse structure 250 and transistor 270 to be connected to each other in series. In some embodiments, the epitaxial structure 418 may be referred to as a portion of the drain structure 270D of the transistor 270 of the memory cell 103B. The VG 344 may be electrically connected to the gate structure 324 of the transistor 270, and the transistor 270 may be gated by the gate structure 334, which can function as WLR2 that allows access of the memory cell 103B. In addition, the transistor 270 has the source structure 270S connected to the MD 306. The VD 316 can couple the MD 306 (and the source structure 270S) to BL1, which may be formed in an upper metallization layer. Further, a second portion of the active region 302 that is overlaid by the gate structure 334 may include a number of nanostructures vertically separated from each other, which can function as channels 416 of the reading transistor 270. The gate structure 334 may function as the gate structure 270G of the reading transistor 270 (FIG. 2). Portions of the active region 302 that are disposed on opposite sides of the gate structure portion 334 are replaced with epitaxial structures 418 and 410, which can function as the source/drain structures 270D and 270S of the reading transistor 270, respectively. In some embodiments, the epitaxial structure 410 may be referred to as a portion of the source structure 270S of the transistor 270 of the memory cell 103B. That is, the reading transistors 230 and 270 may share a same portion of the epitaxial structure 410 to form their respective source structures 230S and 270S, as shown in FIG. 4.

As shown in FIG. 5 and FIG. 6, before forming the dielectric material 402, a liner 502 may be formed to wrap the surfaces of the epitaxial structures 408 and 410, in accordance with some embodiments. After forming the dielectric material 402 on the liner 502, an etching process may be performed to remove a portion of the dielectric material 402 and a portion of the liner 502 over the epitaxial structure 410 to expose a portion of the surface of the epitaxial structure 410 for forming the MD 306. In this state, the other epitaxial structure 408 is covered or buried by the liner 502 and the dielectric material 402.

In some embodiments, the liner 502 may include a low-k material such as SiOCN, SiON, SiN, SiCN, and SiOC. Alternatively, the liner 502 may include aluminum silicate (AlySiOx) or silicide material such as TiSi, TiNiSi, NiSi, WSi, CoSi, or the like. In some examples, the liner 502 may include a dielectric of the metal or a dielectric of the silicide material, such as TiN, TiNiN, NiN, WN, CoN, the like or TiSiN, TiNiSIN, NiSIN, WSIN, CoSiN, or the like. The dielectrics just described are nitrides of the metal or silicide material. In some embodiments in which the liner 502 may include carbon or oxygen. For example, the liner 502 may include TiSiON, TiCN, or the like. The thickness of the liner 502 can be adjusted according to needs, and the embodiments of the present invention are not limited thereto. The liner 502 may be formed by various processes, including a deposition process and an etching process. For instance, the deposition process may include thermal growth, CVD, PVD, and ALD. The deposition process may include depositing the liner 502 as a conformal layer. In this condition, a blanket layer includes silicon nitride and is deposited by a conformal deposition technique, such as an ALD process.

After forming the MD 306, the VDs 316 and 318 may be formed over the epitaxial structures 410 and 408, respectively. Specifically, the VD 316 may be formed on the MD 306 and in physically contact with the MD 306. The VD 316 is formed to (e.g., electrically) couple the MD 306 and the underlying epitaxial structure 410 to the overlying metallization layer (e.g., 326) that functions as BL1 (FIG. 3). In addition, the VD 318 may be formed on the liner 502 and in physically contact with the liner 502. In some embodiments, the VD 318 would stop on the liner 502 and not extend into the epitaxial structure 408. In this case, the liner 502 may be referred to a contact etch stop layer (CESL) for forming the VD 318. In the present embodiment, a portion of the liner 502 sandwiched between the VD 318 and the epitaxial structure 408 can function as the insulator 210C of the anti-fuse structure 210 (FIG. 3). However, the embodiments of the present invention are not limited thereto. In other embodiments, the liner 502 may be omitted, and a portion of the dielectric material 402 sandwiched between the VD 318 and the epitaxial structure 408 can function as the insulator 210C of the anti-fuse structure 210.

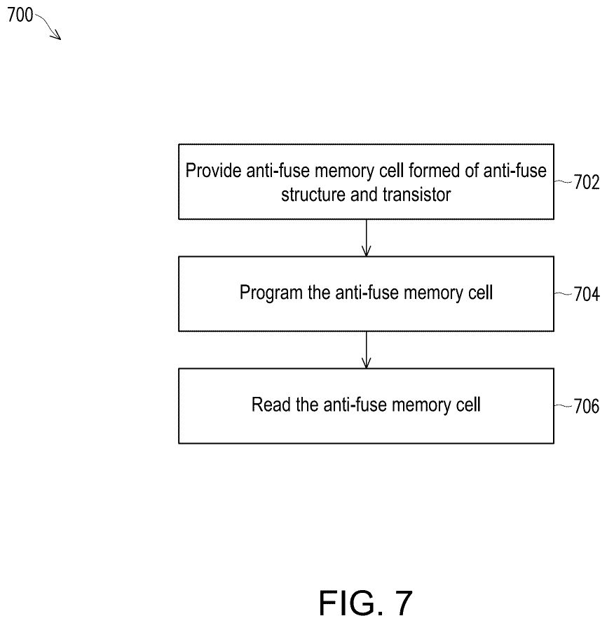

FIG. 7 illustrates a flow chart of an example method 700 for operating (e.g., programming and/or reading) the disclosed anti-fuse memory cell (e.g., 103A and 103B), in accordance with various embodiments. The operations of the method 700 can be performed through one or more features/structures illustrated above. Accordingly, the following embodiment of the method 700 will be described in conjunction with at least some of the figures above. The illustrated embodiment of the method 700 is merely an example. Therefore, it should be understood that any of a variety of operations may be omitted, re-sequenced, and/or added while remaining within the scope of the present disclosure.

The method 700 starts with operation 702 of providing an anti-fuse memory cell formed of an anti-fuse structure and a reading transistor, in accordance with various embodiments. For example, as disclosed herein, the anti-fuse structure (e.g., 210) of the anti-fuse memory cell (e.g., 103A) includes a first electrode (e.g., 210A) implemented as a first via structure (e.g., 318) and a second electrode (e.g., 210B) implemented as an epitaxial structure (e.g., 408) that interpose an insulator (e.g., a portion of the dielectric material 402 (or liner 502) embedding the first via structure 318 and the epitaxial structure 408 therebetween), and the anti-fuse structure (e.g., 210) is electrically coupled to the reading transistor (e.g., 230) in series through the epitaxial structure (e.g., 408). Further, the first electrode of the anti-fuse structure is coupled to a programming word line (e.g., WLP1), and a gate structure (e.g., 304) of the reading transistor may function as or be coupled to a reading word line (e.g., WLR1) with a source structure (e.g., 230S) of the reading transistor coupled to a bit line (e.g., BL1).

Next, the method 700 proceeds to operation 704 of programming the memory cell 103A, in accordance with various embodiments. To program the memory cell 103A, the reading transistor 230 is turned on by supplying a high enough voltage (e.g., a positive voltage corresponding to a logic high state) to its gate structure 304. Prior to, concurrently with or subsequently to the reading transistor 230 being turned on, a sufficiently high voltage (e.g., a breakdown voltage (VBD) which is sometimes referred to as a programming voltage) is applied to WLP1, and a low enough voltage (e.g., a positive voltage or ground voltage corresponding to a logic low state) is applied to BL1. With the reading transistor 230 being turned on, the low voltage (applied on BL1) can be passed to the drain structure 230D (and also the electrically coupled second electrode 210B, e.g., the epitaxial structure 408). As such, the programming voltage VBD can be present across the first electrode 210A (e.g., the via structure 318) and the second electrode 210B thereby causing a breakdown of the interposed insulator 210C.

When operating an array of composed of a number of the disclosed memory cells, leakage current typically present between the gate structure and source/drain structure of an unselected programming transistor can be almost eliminated. The commonly high voltage level of the programming voltage can cause the leakage current to become worse. In the present disclosure, the typical programming transistor is replaced by a non-transistor structure (e.g., the disclosed anti-fuse structure), which in turn minimizes such leakage current.

After the insulator 210C of the anti-fuse structure 210 is broken down, a behavior of the insulator 210C is equivalently resistive. For example, such a broken-down portion of the dielectric material 402 or liner 502 (that is configured as the insulator 210C) may function as a resistor. Before the insulator 210C is broken down, no conduction path exists between the first and second electrodes, 210A and 210B, even if the reading transistor 230 is turned on. After programming the anti-fuse structure 210 (e.g., by breaking down the insulator 210C), a conduction path exists between the first and second electrodes, 210A and 210B (e.g., via the equivalently formed resistor).

Next, the method 700 continues to operation 706 of reading the memory cell 103A, in accordance with various embodiments. To read the memory cell 103A, similarly to the programming, the reading transistor 230 is turned on via WLR1, and BL1 is coupled to a voltage corresponding to the logic low state. In response, a positive voltage is applied to the first electrode 210A of the anti-fuse structure 210 through WLP1. As discussed above, if the insulator 210C of the anti-fuse structure 210 is not broken down, no conduction path exists between the first and second electrodes of the anti-fuse structure 210. Thus, a relatively low current conducts from WLP1, through the anti-fuse structure 210 and the reading transistor 230, and to BL1. If the insulator 210C of the anti-fuse structure 210 is broken down, a conduction path exists between the first and second electrodes of the anti-fuse structure 210. Thus, a relatively high current conducts from WLP1, through the anti-fuse structure 210 and the reading transistor 230, and to BL1.

Such a low current and high current may sometimes be referred to as Ioff and Ion of the memory cell 103A, respectively. A circuit component (e.g., a sense amplifier) of the I/O circuit 108 (FIG. 1), coupled to the BL1 can differentiate Ioff from Ion (or vice versa), and thus determine whether the memory cell 103A presents a logic high (“1”) or a logic low (“0”) based on whether a conduction path is formed in the anti-fuse structure 210. Accordingly, the anti-fuse structure can sometimes be referred to as a memory structure of the anti-fuse memory cell 103A. For example, when Ion is read, the memory cell 103A may present 1; and when Ioff is read, the memory cell 103A may present 0.

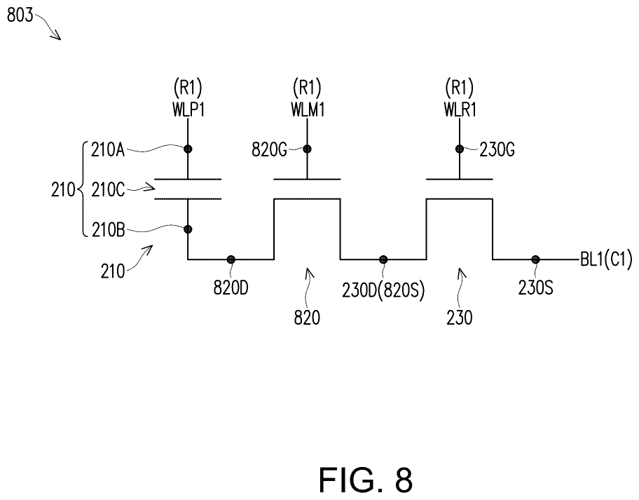

FIG. 8 illustrates an example circuit diagram of a portion of the memory device 100 (e.g., the memory cells 103 are replaced by the memory cells 803), in accordance with some alternative embodiments. In the illustrated example of FIG. 8, an example anti-fuse memory cell 803 is shown. Although only one anti-fuse memory cell 803 is shown, it should be appreciated that the memory array 102 can have any number of anti-fuse memory cells, while remaining within the scope of present disclosure.

Referring to FIG. 8, the memory cell 803 is similar to the memory cell 103A. That is, the configuration of the memory cell 803 is similar to that of the memory cell 103A, and thus the details are omitted herein. The main difference between the memory cell 803 and the memory cell 103A lies in that the memory cell 803 further includes a middle transistor 820 between the anti-fuse structure 210 and the reading transistor 230. Specifically, the memory cell 803 is operatively (e.g., electrically) coupled to a programming word line and a reading word line in row R1 (hereinafter WLP1, WLM1, and WLR1, respectively) and to a bit line in column C1 (hereinafter BL1).

In some embodiments, the memory cell 803 can be operatively coupled to the I/O circuit 108 through the respective WLR, WLM, WLP, and BL for being accessed (e.g., programmed, read). For example, the I/O circuit 108 can cause the row decoder 104 to assert the WLP1, WLM1, and WLR1 and the column decoder 106 to assert the BL1, so as to access the memory cell 103A through the WLP1, WLM1, WLR1, and BL1. Details of programming and reading the memory cell will be discussed in further detail below.

Referring still to FIG. 8, the memory cell 803 includes a (programming) anti-fuse structure 210, a (middle) transistor 820, and a (reading) transistor 230. The programming anti-fuse structure 210 is coupled to the middle transistor 820 and the reading transistor 230 in series. The anti-fuse structure 210 has a first electrode 210A and a second electrode 210B that interpose an insulator 210C; the transistor 820 has a first terminal (implemented as a drain structure) 820D, a second terminal (implemented as a gate structure) 820G, and a third terminal (implemented as a source structure) 820S, and the transistor 230 has a first terminal (implemented as a drain structure) 230D, a second terminal (implemented as a gate structure) 230G, and a third terminal (implemented as a source structure) 230S. In various embodiments, the anti-fuse structure 210 has the first electrode 210A, which is formed as a first via structure (sometimes referred to as “VD”), connected to WLP1. Further, the anti-fuse structure 210 has the second electrode 210B, which is formed as a first epitaxial structure (e.g., the drain structure 820D), thereby serially connecting the anti-fuse structure 210 to the transistors 820 and 230. The transistor 820 is gated by WLM1, with the source structure 820S electrically coupled to the drain structure 230D of the transistor 230. The transistor 230 is gated by WLR1, with the source structure 230S electrically coupled to BL1.

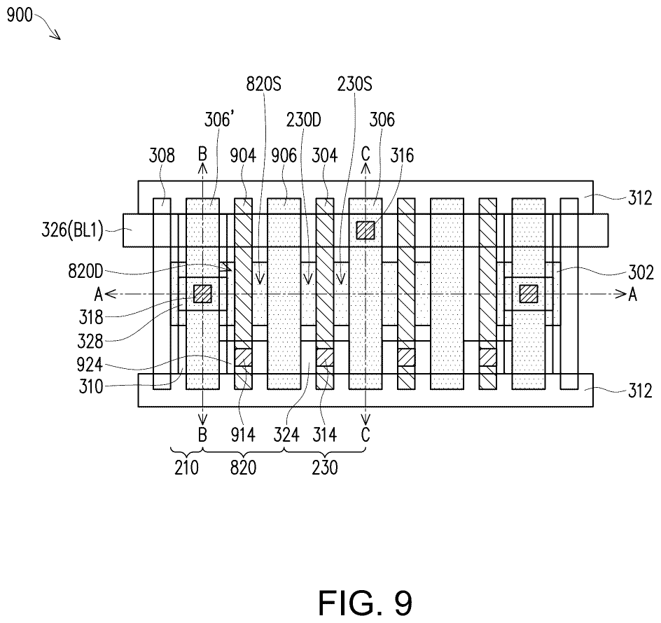

FIG. 9 illustrates an example layout 900 of a portion of the memory array 102, which includes two of the disclosed anti-fuse memory cells coupled to a same bit line (e.g., BL1), in accordance with various embodiments. As will be discussed below, these two memory cells may share (e.g., be formed over) a common active region, which can advantageously reduce an area of the memory array 102 as a whole.

Compared with the layout 300, the layout 900 further includes: a pattern 904 that is configured to form a gate structure (hereinafter “gate structure 904); a pattern 906 that is configured to form a source/drain interconnect structure, e.g., MD, (hereinafter “MD 906”); a pattern 914 that is configured to form a gate via structure, e.g., VG (hereinafter “VG 914”); and a pattern 924 that is configured to form an interconnect structure in a bottommost metallization layer, e.g., M0 (hereinafter “M0 924”). Throughout the present disclosure, the same or similar reference numerals denote the same or similar features unless otherwise excepted.

In some embodiments, the gate structure 904 may travel across a non-edge portion of the active region 302, and the MD 906 may travel across a portion of the active region 302 between the gate structures 304 and 904.

In some embodiments, a first portion of the active region 302 that is overlaid by the gate structure 304 may include a number of nanostructures vertically separated from each other, which can function as a channel of the reading transistor 230 (FIG. 8). The gate structure 304 may function as the gate structure 230G of the reading transistor 230. Portions of the active region 302 that are disposed on opposite sides of the gate structure 304 are replaced with epitaxial structures, which can function as the source/drain structures 230D and 230S of the reading transistor 230 (FIG. 8), respectively. Similarly, a second portion of the active region 302 that is overlaid by the gate structure 904 may include a number of nanostructures vertically separated from each other, which can function as a channel of the middle transistor 820 (FIG. 8). The gate structure 904 may function as the gate structure 820G of the middle transistor 820. Portions of the active region 302 that are disposed on opposite sides of the gate structure 904 are replaced with epitaxial structures, which can function as the source/drain structures 820D and 820S of the middle transistor 820, respectively. It should be noted that the reading transistors 230 and the middle transistor 820 may share a same portion of the active region 302 to form their respective source/drain structures 230D and 820S, as shown in FIG. 9.

The MD 906 is formed to connect to a corresponding one of the source/drain structures. For example, the MD 906 connects to the source/drain structure 408. In some embodiments, a first portion of the source/drain structure 408 may be referred to as the source structure 820S of the middle transistor 820, and a second portion of the source/drain structure 408 may be referred to as the drain structure 230D of the reading transistor 230. In addition, the VG 914 may be formed to connect to the gate structure 904.

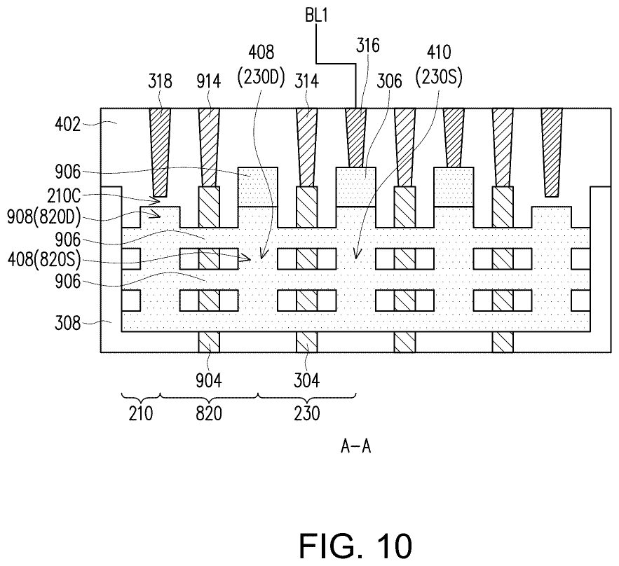

Each of the VGs 314, 914 and VDs 316, 318 is formed to (e.g., electrically) couple an underlying structure to one or more interconnect structures disposed in an upper metallization layer, thereby operatively coupling different anti-fuse memory cells to each other as an array. For example, the VG 314 can couple the gate structure 304 to the M0 324; the VG 914 can couple the gate structure 904 to the M0 924; the VD 318 can be electrically connected to the overlying M0 328 and the VD 316 can couple the MD 306 (and the underlying source structure 230S) to an interconnect structure disposed in an upper metallization layer (e.g., 326) that functions as BL1, which can be better illustrated in the cross-sectional view of FIG. 10.

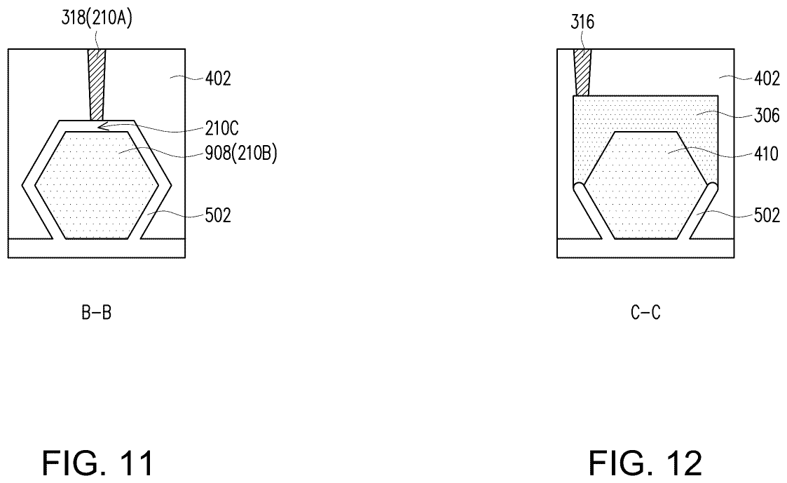

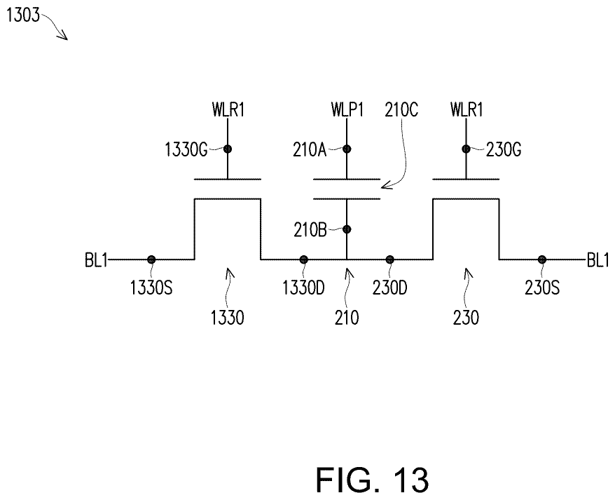

FIG. 10 to FIG. 12 illustrate hybrid cross-sectional views of a portion of the memory array 102 (e.g., the memory cell 803 having the anti-fuse structure 210, the middle transistor 820, and the transistor 230) formed based on the example layout 900 of FIG. 9. Specifically, FIG. 10 includes a cross-section of the portion of the memory array 102, which are cut along line A-A (as indicated in FIG. 9); FIG. 11 includes a cross-section of the portion of the memory array 102, which are cut along line B-B (as indicated in FIG. 9), and FIG. 13 includes a cross-section of the portion of the memory array 102, which are cut along line C-C (as indicated in FIG. 9).

As shown in FIG. 10, the gate structures 304 and 904, the VDs 316 and 318, the VGs 314 and 914, and MDs 306 and 906 are embedded in a dielectric material 402. The dielectric material 402 includes the above-described low-k dielectric material. As at least partially described above, the VD 318 can function as the first electrode 210A of the anti-fuse structure 210 of the memory cell 803 (FIG. 8), and the epitaxial structure 908 (e.g., the drain structure 820D) can function as the second electrode 210B of the anti-fuse structure 210. A portion of the dielectric material 402 sandwiched between the VD 318 and the epitaxial structure 908 can function as the insulator 210C of the anti-fuse structure 210. The VD 318 may be electrically connected to the M0 328 (FIG. 9) and can function as WLP1 configured to program the anti-fuse structure 210. The epitaxial structure 908 may be electrically connected to the drain structure 820D of the transistor 820 of the memory cell 803, thereby causing the anti-fuse structure 210 and transistor 820 to be connected to each other in series. In some embodiments, the epitaxial structure 908 may be referred to as a portion of the drain structure 820D of the transistor 820 of the memory cell 803. The VG 914 may be electrically connected to the gate structure 904 of the transistor 820, and the transistor 820 may be gated by the gate structure 904, which can function as WLM1 that allows access of the memory cell 803. In addition, the transistor 820 has the source structure 820S connected to the MD 906 and the drain structure 230D of the transistor 230. The VG 314 may be electrically connected to the gate structure 304 of the transistor 230, and the transistor 230 may be gated by the gate structure 304, which can function as WLR1 that allows access of the memory cell 803. In addition, the transistor 230 has the source structure 230S connected to the MD 306. The VD 316 can couple the MD 306 (and the source structure 230S) to BL1, which may be formed in an upper metallization layer. In some embodiments, the middle transistor 820 may divide the voltage of an end of the anti-fuse structure 210 to reduce a voltage stress on the reading transistor 230.

Further, a portion of the active region 302 that is overlaid by the gate structure 904 may include a number of nanostructures vertically separated from each other, which can function as channels 906 of the middle transistor 820. The gate structure 904 may function as the gate structure 820G of the middle transistor 820 (FIG. 8). Portions of the active region 302 that are disposed on opposite sides of the gate structure portion 904 are replaced with epitaxial structures 908 and 408, which can function as the source/drain structures 820D and 820S of the middle transistor 820, respectively. In addition, portions of the active region 302 that are disposed on opposite sides of the gate structure portion 304 are replaced with epitaxial structures 408 and 410, which can function as the source/drain structures 230D and 230S of the reading transistor 230, respectively. In some embodiments, the epitaxial structure 408 may be referred to as a portion of the source structure 820S of the transistor 820 and a portion of the drain structure 230D of the transistor 230.

As shown in FIG. 11 and FIG. 12, in the present embodiment, a portion of the liner 502 sandwiched between the VD 318 and the epitaxial structure 908 can function as the insulator 210C of the anti-fuse structure 210 (FIG. 8). However, the embodiments of the present invention are not limited thereto. In other embodiments, the liner 502 may be omitted.

FIG. 13 illustrates an example circuit diagram of a portion of the memory device 100 (e.g., the memory cells 103 are replaced by the memory cells 1303), in accordance with some alternative embodiments. In the illustrated example of FIG. 13, an example anti-fuse memory cell 1303 is shown. Although only one anti-fuse memory cell 1303 is shown, it should be appreciated that the memory array 102 can have any number of anti-fuse memory cells, while remaining within the scope of present disclosure.

Referring to FIG. 13, the memory cell 1303 is similar to the memory cell 803. That is, the configuration of the memory cell 1303 is similar to that of the memory cell 803, and thus the details are omitted herein. The main difference between the memory cell 1303 and the memory cell 803 lies in that the memory cell 1303 may include an anti-fuse structure disposed between two reading transistors. For example, the memory cell 1303 may include a (programming) anti-fuse structure 210 disposed between two (reading) transistors 230 and 1330. The programming anti-fuse structure 210 may be coupled to the reading transistors 230 and 1330 in series.

In some embodiments, the anti-fuse structure 210 has a first electrode 210A and a second electrode 210B that interpose an insulator 210C; the transistor 1330 has a first terminal (implemented as a drain structure) 1330D, a second terminal (implemented as a gate structure) 1330G, and a third terminal (implemented as a source structure) 1330S, and the transistor 230 has a first terminal (implemented as a drain structure) 230D, a second terminal (implemented as a gate structure) 230G, and a third terminal (implemented as a source structure) 230S. In various embodiments, the anti-fuse structure 210 has the first electrode 210A, which is formed as a first via structure (sometimes referred to as “VD”), connected to WLP1. Further, the anti-fuse structure 210 has the second electrode 210B, which is formed as a first epitaxial structure (e.g., the drain structures 1330D and 230D), thereby serially connecting the anti-fuse structure 210 to the transistors 1330 and 230. The transistor 1330 is gated by WLR1, with the drain structure 1330D electrically coupled to the second electrode 210B of the anti-fuse structure 210, and the source structure 1330S electrically coupled to BL1. The transistor 230 is gated by WLR1, with the drain structure 230D electrically coupled to the second electrode 210B of the anti-fuse structure 210, and the source structure 230S electrically coupled to BL1.

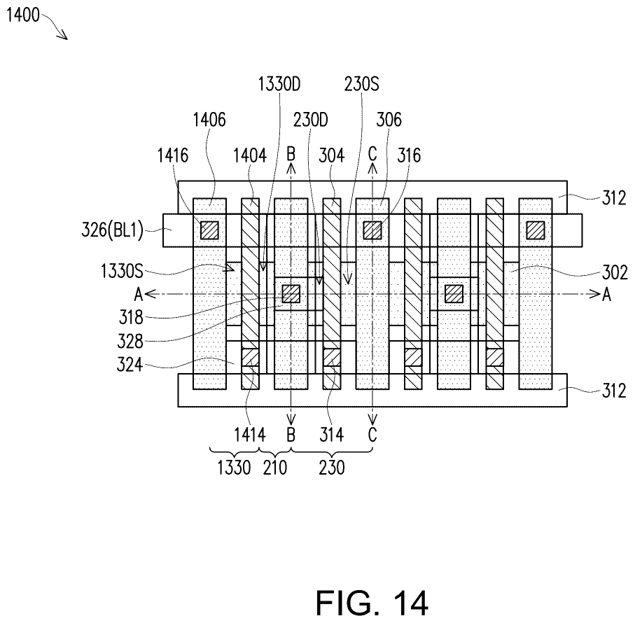

FIG. 14 illustrates an example layout 1400 of a portion of the memory array 102, which includes two of the disclosed anti-fuse memory cells coupled to a same bit line (e.g., BL1), in accordance with various embodiments. As will be discussed below, these two memory cells may share (e.g., be formed over) a common active region, which can advantageously reduce an area of the memory array 102 as a whole.

Compared with the layout 300, the layout 1400 further includes: a pattern 1404 that is configured to form a gate structure (hereinafter “gate structure 1404); a pattern 1406 that is configured to form a source/drain interconnect structure, e.g., MD, (hereinafter “MD 1406”); a pattern 1414 that is configured to form a gate via structure, e.g., VG (hereinafter “VG 1414”); and a pattern 1416 that is configured to form a source/drain via structure, e.g., VD (hereinafter “VD 1416”). Throughout the present disclosure, the same or similar reference numerals denote the same or similar features unless otherwise excepted.

In some embodiments, the gate structure 1404 may travel across a non-edge portion of the active region 302, and the MD 1406 may travel across a portion of the active region 302 at one side of the gate structure 1404.

In some embodiments, a first portion of the active region 302 that is overlaid by the gate structure 304 may include a number of nanostructures vertically separated from each other, which can function as a channel of the reading transistor 230 (FIG. 13). The gate structure 304 may function as the gate structure 230G of the reading transistor 230. Portions of the active region 302 that are disposed on opposite sides of the gate structure 304 are replaced with epitaxial structures, which can function as the source/drain structures 230D and 230S of the reading transistor 230 (FIG. 13), respectively. Similarly, a second portion of the active region 302 that is overlaid by the gate structure 1404 may include a number of nanostructures vertically separated from each other, which can function as a channel of the reading transistor 1330 (FIG. 8). The gate structure 1404 may function as the gate structure 1330G of the reading transistor 1330. Portions of the active region 302 that are disposed on opposite sides of the gate structure 1404 are replaced with epitaxial structures, which can function as the source/drain structures 1330D and 1330S of the reading transistor 1330, respectively. It should be noted that the reading transistors 230 and 1330 may share a same portion of the active region 302 to form their respective source/drain structures 230D and 1330D, as shown in FIG. 13.

The MD 1406 is formed to connect to a corresponding one of the source/drain structures. For example, the MD 1406 connects to the source structure 1330S of the reading transistor 1330, and the MD 306 connects to the source structure 230S of the reading transistor 230. In addition, the VG 1414 may be formed to connect to the gate structure 1404.

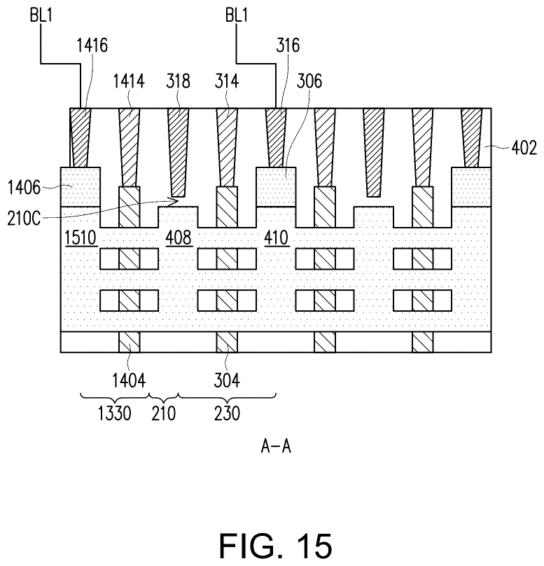

Each of the VGs 314, 1414 and VDs 316, 318 is formed to (e.g., electrically) couple an underlying structure to one or more interconnect structures disposed in an upper metallization layer, thereby operatively coupling different anti-fuse memory cells to each other as an array. For example, the VG 314 can couple the gate structure 304 to the M0 324; the VG 1414 can couple the gate structure 1404 to the M0 324; the VD 318 can be electrically connected to the overlying M0 328 and the VD 316 can couple the MD 306 (and the underlying source structure 230S) to an interconnect structure disposed in an upper metallization layer (e.g., 326) that functions as BL1, which can be better illustrated in the cross-sectional view of FIG. 15.

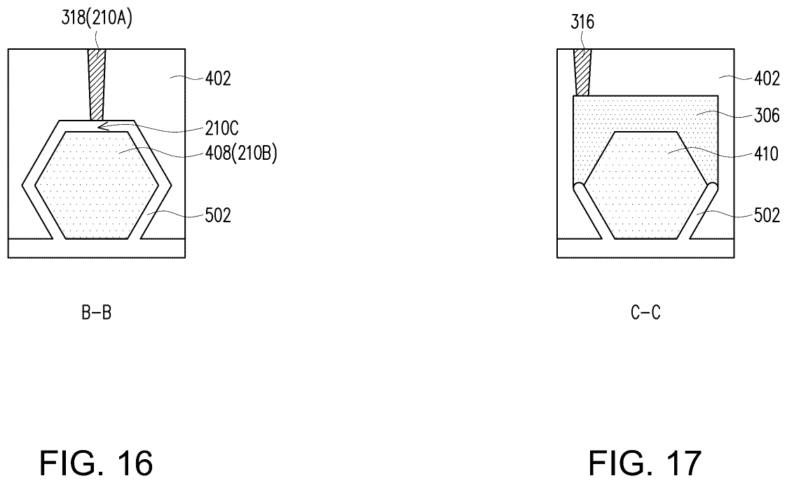

FIG. 15 to FIG. 17 illustrate hybrid cross-sectional views of a portion of the memory array 102 (e.g., the memory cell 1303 having the anti-fuse structure 210 and the transistors 230 and 1330) formed based on the example layout 1400 of FIG. 14. Specifically, FIG. 15 includes a cross-section of the portion of the memory array 102, which are cut along line A-A (as indicated in FIG. 14); FIG. 16 includes a cross-section of the portion of the memory array 102, which are cut along line B-B (as indicated in FIG. 14), and FIG. 17 includes a cross-section of the portion of the memory array 102, which are cut along line C-C (as indicated in FIG. 14).

As shown in FIG. 15, the gate structures 304 and 1404, the VDs 316, 318, and 1416, the VGs 314 and 1414, and MDs 306 and 1406 are embedded in a dielectric material 402. The dielectric material 402 includes the above-described low-k dielectric material. As at least partially described above, the VD 318 can function as the first electrode 210A of the anti-fuse structure 210 of the memory cell 1303 (FIG. 13), and the epitaxial structure 408 (e.g., the drain structures 1330D and 230D) can function as the second electrode 210B of the anti-fuse structure 210. A portion of the dielectric material 402 sandwiched between the VD 318 and the epitaxial structure 408 can function as the insulator 210C of the anti-fuse structure 210. The VD 318 may be electrically connected to the M0 328 (FIG. 14) and can function as WLP1 configured to program the anti-fuse structure 210. The epitaxial structure 408 may be electrically connected to the drain structure 1330D of the transistor 1330 and the drain structure 230D of the transistor 230 of the memory cell 1303, thereby causing the anti-fuse structure 210 and the transistors 1330 and 230 to be connected to each other in series. In some embodiments, the epitaxial structure 408 may be referred to as a portion of the drain structure 1330D of the transistor 1330 and a portion of the drain structure 230D of the transistor 230 of the memory cell 1303. The VG 1414 may be electrically connected to the gate structure 1404 of the transistor 1330, and the transistor 1330 may be gated by the gate structure 1404, which can function as WLR1 that allows access of the memory cell 1303. In addition, the transistor 1330 has the source structure 1330S connected to the MD 1406 which is electrically coupled to BL1 through the VD 1416. Similarly, the VG 314 may be electrically connected to the gate structure 304 of the transistor 230, and the transistor 230 may be gated by the gate structure 304, which can function as WLR1 that allows access of the memory cell 1303. In addition, the transistor 230 has the source structure 230S connected to the MD 306 which is electrically coupled to BL1 through the VD 316. In this case, the current conducts from WLP1, through the anti-fuse structure 210 and the reading transistors 230 and 1330, and to BL1, thereby achieving a bidirectional electrical path.

Further, portions of the active region 302 that are disposed on opposite sides of the gate structure portion 1404 are replaced with epitaxial structures 1510 and 408, which can function as the source/drain structures 1330S and 1330D of the reading transistor 1330, respectively. In addition, portions of the active region 302 that are disposed on opposite sides of the gate structure portion 304 are replaced with epitaxial structures 408 and 410, which can function as the source/drain structures 230D and 230S of the reading transistor 230, respectively. In some embodiments, the epitaxial structure 408 may be referred to as a portion of the drain structure 1330D of the transistor 1330 and a portion of the drain structure 230D of the transistor 230.

As shown in FIG. 16 and FIG. 17, in the present embodiment, a portion of the liner 502 sandwiched between the VD 318 and the epitaxial structure 408 can function as the insulator 210C of the anti-fuse structure 210 (FIG. 13). However, the embodiments of the present invention are not limited thereto. In other embodiments, the liner 502 may be omitted.

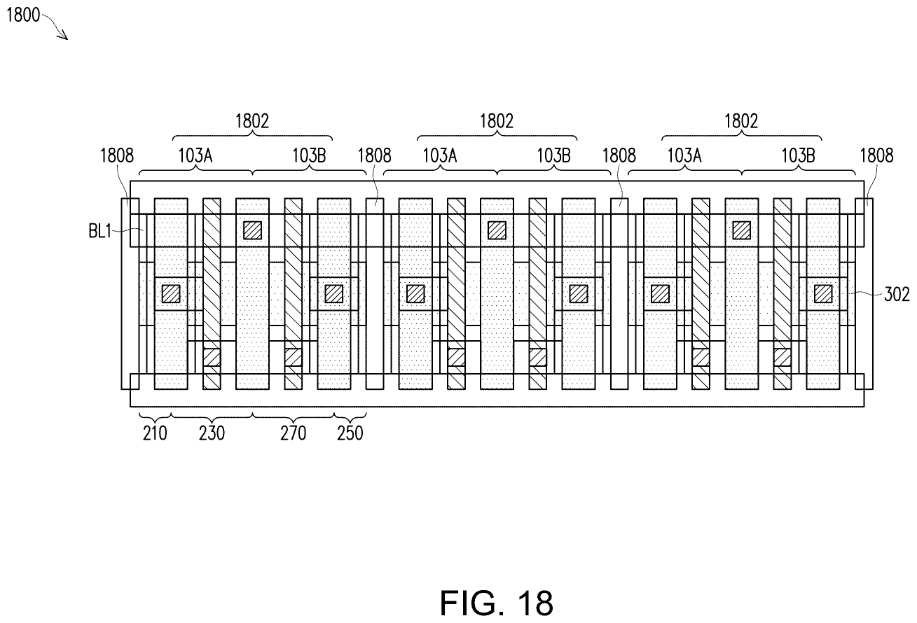

FIG. 18 illustrates an example layout 1800 of a portion of the memory array 102, which includes a plurality of unit cells 1802 coupled to a same bit line (e.g., BL1). In some embodiments, one of the unit cells 1802 may include a pair of the memory cells 103A and 103B coupled in series, as mentioned in the above embodiments, and thus the details are omitted herein. It should be noted that the unit cells 1802 are separated from each other by one or more isolation structures (e.g., CPODE structures) 1808. In some embodiments, the isolation structures 1808 can cut off the continuous active region 302 to define the boundary of each unit cell 1802. In some embodiments, the memory array 102 (FIG. 1) may include the same type of unit cell or different types of unit cells. For example, each unit cell includes a pair of the memory cells 103A and 103B (e.g., a one-transistor one-capacitor (1T1C) configuration), as shown in FIG. 3. Alternatively, one unit cell may include a pair of the memory cells 103A and 103B (e.g., 1T1C configuration), as shown in FIG. 3; and another unit cell may include a pair of the memory cells 803 (e.g., a two-transistor one-capacitor (2T1C) configuration), as shown in FIG. 9.

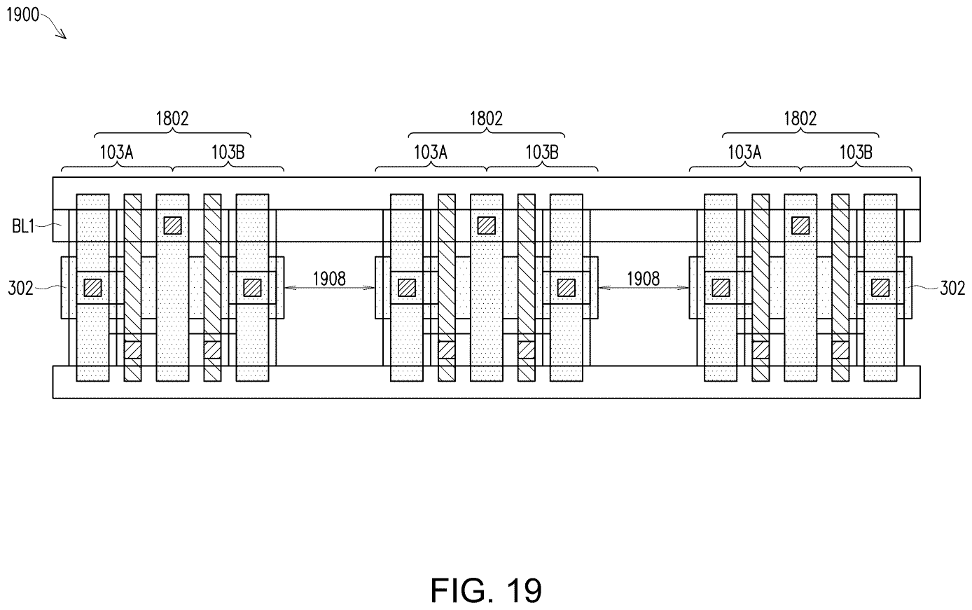

FIG. 19 illustrates an example layout 1900 of a portion of the memory array 102, which includes a plurality of unit cells 1802 coupled to a same bit line (e.g., BL1). The layout 1900 is similar to the layout 1800 illustrated in FIG. 18, but the layout 1900 is free of the CPODE structures between the unit cells 1802. In the present embodiment, the layout 1900 may keep adjacent unit cells 1802 apart from each other by a distance 1908 to avoid interference between adjacent unit cells 1802. As shown in FIG. 19, the active region 302 may be divided into a plurality active segments and the adjacent active segments may be separated from each other by the distance 1908. The distance 1908 can be adjusted according to the design and technical nodes, and the present invention is not limited thereto.

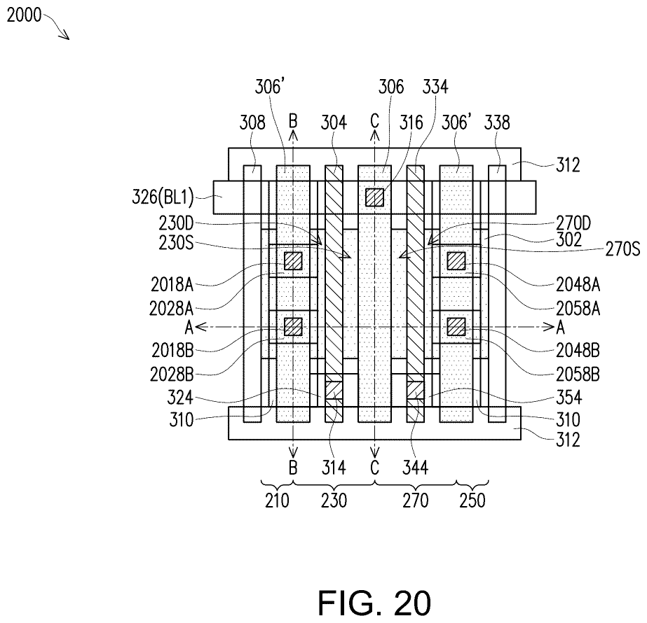

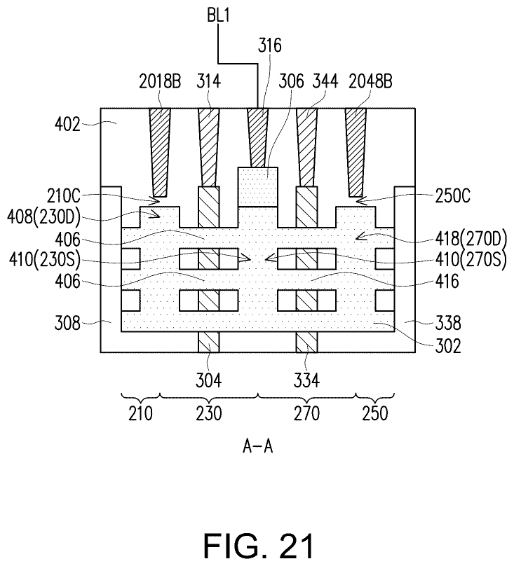

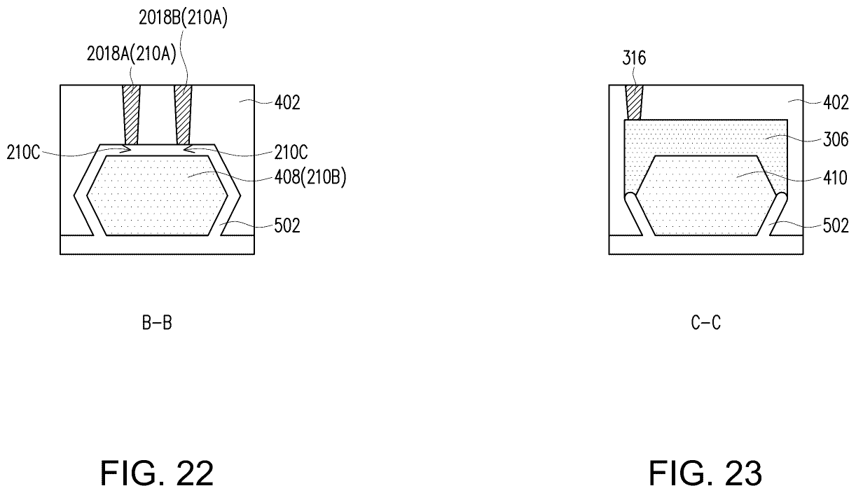

FIG. 20 illustrates an example layout to fabricate a pair of the memory cells of FIG. 2, in accordance with some alternative embodiments. FIG. 21 to FIG. 23 illustrate cross-sectional views of one of the memory cells, made based on the layout of FIG. 20 taken along the line A-A, the line B-B, and line C-C respectively, in accordance with some alternative embodiments.

Referring to FIG. 20 to FIG. FIG. 23, the layout 2000 is similar to the layout 300 illustrated in FIG. 3, but the layout 2000 further includes more than one VD landing on the drain structure 230D of the reading transistor 230. For example, the VDs 2018A and 2018B can function as the first electrode 210A and the drain structure 230D directly below the VDs 2018A and 2018B can function as the second electrode 210B of the anti-fuse structure 210; and the VDs 2048A and 2048B can function as the first electrode 250A and the drain structure 270D directly below the VDs 2048A and 2048B can function as the second electrode 250B of the anti-fuse structure 250. Although only two VDs 2018A and 2018B is landed on the drain structure 230D of the reading transistor 230, the embodiments of the present disclosure are not limited thereto. In other embodiments, the number of the VDs 2018A and 2018B can be adjusted by the needs.

Each of the VDs 2018A and 2018B and the VDs 2048A and 2048B is formed to (e.g., electrically) couple an underlying structure to one or more interconnect structures disposed in an upper metallization layer, thereby operatively coupling different anti-fuse memory cells to each other as an array. For example, the VDs 2018A and 2018B can be electrically connected to the overlying M0 2028A and M0 2028B respectively; and the VDs 2048A and 2048B can be electrically connected to the overlying M0 2058A and M0 2058B respectively. In such embodiment, as long as one of the VDs 2018A and 2018B can cause a breakdown of the interposed insulator 210C, the selected memory cell can be programmed. That is, using more than one VD as the first electrode 210A of the anti-fuse structure 210 can effectively improve the yield of the memory device.

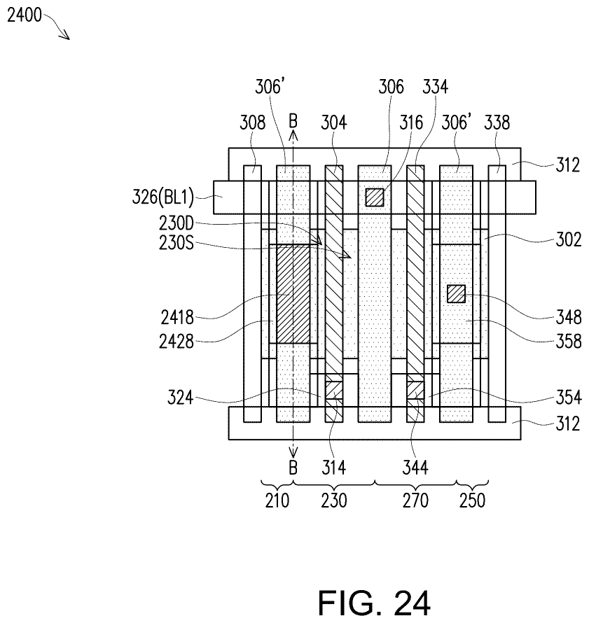

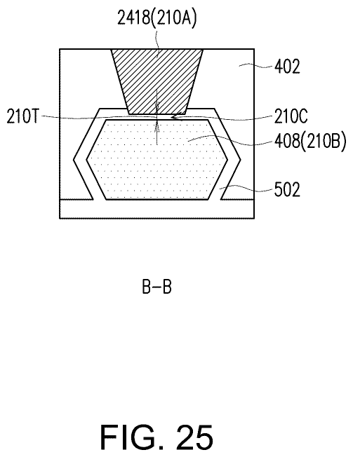

FIG. 24 illustrates an example layout to fabricate a pair of the memory cells of FIG. 2, in accordance with some other embodiments. FIG. 25 illustrates a cross-sectional view of one of the memory cells, made based on the layout of FIG. 24 taken along the line B-B, in accordance with some embodiments.

Referring to FIG. 24 to FIG. FIG. 25, the layout 2400 is similar to the layout 300 illustrated in FIG. 3, but the layout 2400 has a VD with a larger cross-sectional area. For example, the VD 2418 can function as the first electrode 210A and the drain structure 230D directly below the VD 2418 can function as the second electrode 210B of the anti-fuse structure 210. In some embodiments, the VD 2418 has the same horizontal width (along the X-direction) as the MD 306′ and the same longitudinal length(along the Y-direction) as the M0 2428. In this case, the process of forming a larger VD 2418 can effectively control the thickness of the insulator 210C (e.g., the liner 502) between the VD 2418 and the underlying epitaxial structure 408 to be thinner. In some embodiments, the thinner thickness 210T of the insulator 210C of the anti-fuse structure 210 can reduce the breakdown voltage (which is sometimes referred to as a programming voltage) for the advanced technology.

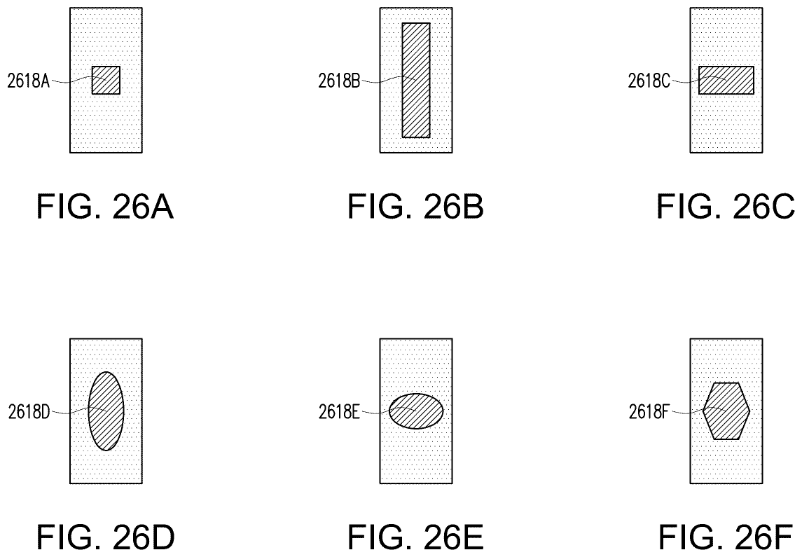

In some embodiments, the shape of the VD 2418 (i.e., the first electrode 210A) can be adjusted according to design requirements, and the embodiments of the present disclosure are not limited thereto. For example, the VD 2618A has a square top-view shape (as shown in FIG. 26A); the VD 2618B has a rectangular top-view shape with a long side extending along the Y-direction (as shown in FIG. 26B); the VD 2618C has a rectangular top-view shape with a long side extending along the X-direction (as shown in FIG. 26C); the VD 2618D has an elliptical top-view shape with a long axis extending along the Y-direction (as shown in FIG. 26D); the VD 2618E has an elliptical top-view shape with a long axis extending along the X-direction (as shown in FIG. 26E); and the VD 2618E has a hexagonal top-view shape (as shown in FIG. 26E), a circular top-view shape, a polygonal top-view shape, or a combination thereof.

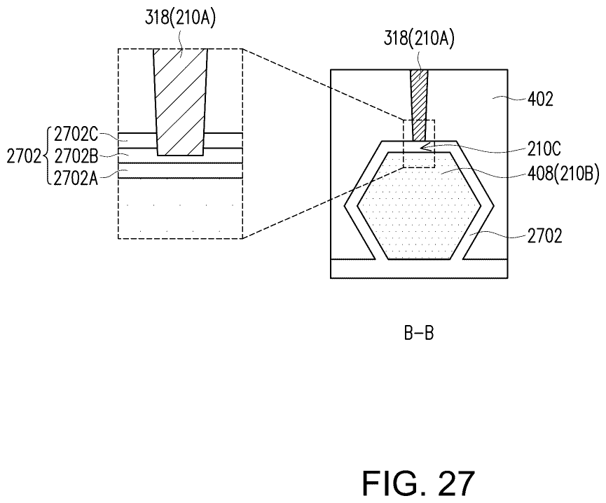

FIG. 27 illustrates a cross-sectional view of one of the memory cells, made based on the layout of FIG. 3 taken along the line B-B, in accordance with some alternative embodiments.

Referring to FIG. 27, the insulator 210C (e.g., the liner 2702) between the first and second electrodes, 210A and 210B may be a multi-layered structure. For example, the liner 2702 may include a first material layer 2702A, a second material layer 2702B, and a third material layer 2702C. In some embodiments, the first material layer 2702A, the second material layer 2702B, and the third material layer 2702C may have different etching selectivities in the process of forming the VD 318. For example, the third material layer 2702C has a third etching rate greater than a second etching rate of the second material layer 2702B; and the second material layer 2702B has the second etching rate greater than a first etching rate of the first material layer 2702A. In such embodiment, the liner 2702 with the multi-layered structure can effectively control the thickness of the insulator 210C between the VD 318 and the underlying epitaxial structure 408 to a desired thickness. Although only the three-layered structure of the liner 2702 is illustrated in the enlarged view of FIG. 27, the embodiments of the present disclosure are not limited thereto. In other embodiments, the number of layers of the liner 2702 can be adjusted by the needs. In some embodiments, the first material layer 2702A, the second material layer 2702B, and the third material layer 2702C may have different dielectric materials. In some alternative embodiments, the first material layer 2702A, the second material layer 2702B, and the third material layer 2702C may have the same dielectric material with different dopants or different doping concentrations.

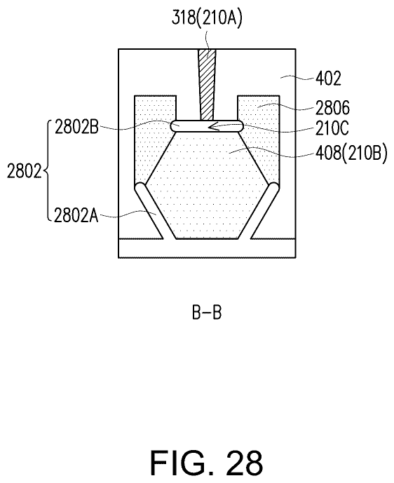

FIG. 28 illustrates a cross-sectional view of one of the memory cells, made based on the layout of FIG. 3 taken along the line B-B, in accordance with some other embodiments.

Referring to FIG. 28, the liner 2802 may partially cover the surface of the epitaxial structure 408, as long as there is an insulator between the VD 318 and the epitaxial structure 408 to separate from the VD 318 and the epitaxial structure 408. For example, the liner 2802 includes a first portion 2802A covering the lower portion of the epitaxial structure 408 and a second portion 2802B covering the top surface of the epitaxial structure 408, thereby exposing a portion of the surface of the epitaxial structure 408 having the MD 2806 formed thereon. In such embodiment, additional VD may be formed on the MD 2806 to increase the flexibility of routing.

According to some embodiments, a memory device includes a first memory cell disposed over an active region. The first memory cell may include: a first transistor comprising: a first gate structure extending across the active region, a first source/drain structure and a second source/drain structure disposed on the active region at opposite sides of the first gate structure; and a first anti-fuse structure connected in series with the first transistor, and comprising: a first electrode over the first source/drain structure, the first source/drain structure used as a second electrode and a first insulator vertically sandwiched between the first electrode and the second electrode.

According to some embodiments, a memory device includes: an active region extending along a first direction; a first gate structure extending along a second direction different from the first direction and across the active region to divide the active region into a first source/drain structure and a second source/drain structure; an insulator overlying the first source/drain structure; a first interconnect structure overlying the second source/drain structure; and a first via vertically disposed on the insulator and separated from the first source/drain structure by the insulator to form a first anti-fuse structure.

According to some embodiments, a method for operating a memory device includes: providing a first memory cell over an active region. The first memory cell may include: a first transistor comprising: a first gate structure extending across the active region, a first source/drain structure and a second source/drain structure disposed on the active region at opposite sides of the first gate structure; and a first anti-fuse structure connected in series with the first transistor, and comprising: a first electrode over the first source/drain structure, the first source/drain structure used as a second electrode and a first insulator vertically sandwiched between the first electrode and the second electrode. The method further includes: activating the first transistor of the first memory cell by applying a first voltage to the first gate structure of the first transistor; and breaking down the first insulator by applying a second voltage on the first electrode, thereby programming the first memory cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a first memory cell, disposed over an active region and comprising:
a first transistor comprising: a first gate structure extending across the active region, a first source/drain structure and a second source/drain structure disposed on the active region at opposite sides of the first gate structure; and
a first anti-fuse structure connected in series with the first transistor, and comprising: a first electrode over the first source/drain structure, the first source/drain structure used as a second electrode and a first insulator vertically sandwiched between the first electrode and the second electrode.

2. The memory device of claim 1, further comprising:
a first interconnect structure overlying the second source/drain structure;
a bit line disposed over the first interconnect structure and extending across the first interconnect structure; and
a first via vertically disposed between the bit line and the first interconnect structure.

3. The memory device of claim 1, wherein a programming voltage applied to the first electrode is configured to break down the first insulator.

4. The memory device of claim 1, further comprising:
a second memory cell, comprising:
a second transistor comprising: a second gate structure extending across the active region, a third source/drain structure and a fourth source/drain structure disposed on the active region at opposite sides of the second gate structure, wherein the third source/drain structure is connected to the second source/drain structure to form a common source/drain structure; and
a second anti-fuse structure connected in series with the second transistor, and comprising: a third electrode over the fourth source/drain structure, the fourth source/drain structure used as a fourth electrode and a second insulator vertically sandwiched between the third electrode and the fourth electrode.

5. The memory device of claim 1, further comprising:
a second transistor comprising: a second gate structure extending across the active region, a third source/drain structure and a fourth source/drain structure disposed on the active region at opposite sides of the second gate structure, wherein the third source/drain structure is connected to the second source/drain structure to form a common source/drain structure; and
a first interconnect structure overlying the fourth source/drain structure;
a bit line disposed over the first interconnect structure and extending across the first interconnect structure; and
a first via vertically disposed between the bit line and the first interconnect structure.

6. The memory device of claim 1, further comprising:
a second transistor comprising: a second gate structure extending across the active region, a third source/drain structure and a fourth source/drain structure disposed on the active region at opposite sides of the second gate structure, wherein the third source/drain structure is connected to the first source/drain structure to form a common source/drain structure;
a first interconnect structure overlying the second source/drain structure;
a bit line disposed over the first interconnect structure and extending across the first interconnect structure;
a first via vertically disposed between the bit line and the first interconnect structure;
a second interconnect structure overlying the fourth source/drain structure, wherein the bit line extends between the first interconnect structure and the second interconnect structure and across the second interconnect structure; and
a second via vertically disposed between the bit line and the second interconnect structure.

7. The memory device of claim 1, wherein the active region extends continuously along a first direction.

8. The memory device of claim 7, further comprising: an isolation structure extending along a second direction different from the first direction, and dividing the active region into at least two active segments.

9. The memory device of claim 1, further comprising: a third electrode located over the first source/drain structure and at the same level as the first electrode, wherein a programmed voltage applied to the third electrode is configured to breakdown the first insulator.

10. The memory device of claim 1, wherein a top-view shape of the first electrode comprises a square top-view shape, a rectangular top-view shape, a circular top-view shape, an elliptical top-view shape, a polygonal top-view shape, or a combination thereof.

11. The memory device of claim 1, wherein the first insulator comprises:
a first material layer directly contacting the second electrode;
a second material layer overlying the first material layer; and
a third material layer overlying the second material layer, wherein during the etching process of forming the first electrode, the third material layer has a third etching rate greater than a second etching rate of the second material layer, and the second etching rate of the second material layer is greater than a first etching rate of the first material layer.

12. The memory device of claim 1, wherein the first insulator completely covers the surface of the second electrode.

13. The memory device of claim 1, wherein the first insulator covers a first portion of the second electrode, and the memory device further comprises a second interconnect structure covering a second portion of the second electrode that is different from the first portion.

14. A memory device, comprising:
an active region extending along a first direction;
a first gate structure extending along a second direction different from the first direction and across the active region to divide the active region into a first source/drain structure and a second source/drain structure;
an insulator overlying the first source/drain structure;
a first interconnect structure overlying the second source/drain structure; and
a first via vertically disposed on the insulator and separated from the first source/drain structure by the insulator to form a first anti-fuse structure.

15. The memory device of claim 14, further comprising:
a second via vertically disposed on the first interconnect structure, and electrically coupling the first interconnect structure and the second source/drain structure to the bit line.

16. The memory device of claim 14, further comprising:
a second gate structure disposed side by side with the first gate structure, wherein the second gate structure extending along the second direction and across the active region to divide the active region into a third source/drain structure and a fourth source/drain structure, and the third source/drain structure is connected to the second source/drain structure to form a common source/drain structure;
a second interconnect structure overlying the fourth source/drain structure; and
a second via vertically disposed on the second interconnect structure and electrically coupling the second interconnect structure and the fourth source/drain structure to the bit line.

17. The memory device of claim 14, further comprising:
a second gate structure disposed side by side with the first gate structure, wherein the second gate structure extending along the second direction and across the active region to divide the active region into a third source/drain structure and a fourth source/drain structure, and the third source/drain structure is connected to the first source/drain structure to form a common source/drain structure;
a second interconnect structure overlying the fourth source/drain structure;
a second via vertically disposed on the first interconnect structure and electrically coupling the first interconnect structure and the second source/drain structure to the bit line; and
a third via vertically disposed on the second interconnect structure and electrically coupling the second interconnect structure and the fourth source/drain structure to the bit line.

18. A method for operating a memory device, comprising:
providing a first memory cell over an active region and the first memory cell comprising:
a first transistor comprising: a first gate structure extending across the active region, a first source/drain structure and a second source/drain structure disposed on the active region at opposite sides of the first gate structure; and
a first anti-fuse structure connected in series with the first transistor, and comprising: a first electrode over the first source/drain structure, the first source/drain structure used as a second electrode and a first insulator vertically sandwiched between the first electrode and the second electrode;
activating the first transistor of the first memory cell by applying a first voltage to the first gate structure of the first transistor; and
breaking down the first insulator by applying a second voltage on the first electrode, thereby programming the first memory cell.

19. The method of claim 18, wherein the first memory cell further comprises:
a first interconnect structure overlying the second source/drain structure;
a bit line disposed over the first interconnect structure and extending across the first interconnect structure; and
a first via vertically disposed between the bit line and the first interconnect structure.

20. The method of claim 18, further comprising:
providing a second memory cell over the active region and the second memory comprising:
a second transistor comprising: a second gate structure extending across the active region, a third source/drain structure and a fourth source/drain structure disposed on the active region at opposite sides of the second gate structure, wherein the third source/drain structure is connected to the second source/drain structure to form a common source/drain structure; and
a second anti-fuse structure connected in series with the second transistor, and comprising: a third electrode over the fourth source/drain structure, the fourth source/drain structure used as a fourth electrode and a second insulator vertically sandwiched between the third electrode and the fourth electrode;
activating the second transistor of the second memory cell by applying a third voltage to the second gate structure of the second transistor; and
breaking down the second insulator by applying a fourth voltage on the third electrode, thereby programming the second memory cell.
